(19) United States
(12) Patent Application Publication
(10) Pub. No.: US 2016/0118361 A1
(43) Pub. Date: Apr. 28, 2016

(54) INTEGRATED CIRCUIT PACKAGE STRUCTURE AND INTERFACE AND CONDUCTIVE CONNECTOR ELEMENT FOR USE WITH SAME

(71) Applicant: George S. Karpati, Quakertown, PA (US)

(72) Inventor: George S. Karpati, Quakertown, PA (US)

(73) Assignee: Infinera Corporation

(21) Appl. No.: 14/525,465

(22) Filed: Oct. 28, 2014

(51) Int. Cl. H01L 23/00

(52) U.S. Cl. CPC H01L 24/72; H01L 24/90

(57) ABSTRACT

Consistent with the present disclosure, a conductive connector element for use with a rigid or flexible insulating substrate to electrically couple first and second electrically conductive contact surfaces is provided. The conductive connector element comprises an electrically conductive deformable material and a shape-memory alloy. The conductive connector element is sized and shaped to fit in an opening provided through the insulating substrate and the shape-memory alloy and the electrically conductive deformable material are mechanically coupled such that a thermally induced deformation of the shape-memory alloy causes a mechanical deformation of the electrically conductive deformable material and thereby aids in the electrical coupling of the first and second electrically conductive contact surfaces through the connector element when the connector element is disposed in the opening provided through the insulating substrate. IC package structures and interfaces incorporating such conductive connector elements are also provided.

### BACKGROUND

In the production of electronic devices, it is oftentimes necessary to provide an interface for electrically coupling two or more electrically conductive contact surfaces. For example, when mounting an integrated circuit (IC) chip to a substrate, rather than directly mounting the IC chip to the substrate, the IC chip may be mounted to the substrate through the use of an interface for electrically connecting the electrically conductive contact pads of the IC chip to corresponding electrically conductive contact pads of the substrate. One example of such an interface is an interposer. The term “interposer” as used herein refers to an electrical interface providing routing between one socket or connection to another. The purpose of an interposer is generally to spread a connection to a wider pitch or to reroute a connection to a different connection. A typical interposer example application is for providing routing between an integrated circuit (IC) die to a ball grid array (BGA) on a substrate, such as the IC die on the interposer on a BGA substrate.

In one method for forming interposers, dielectrically lined through-vias are formed in a substrate, and then are filled with a metal. Electrically conductive contacts are connected to the metal filled vias by, for example, solder balls, solder pads or bonding wires, such that the metal filled vias provide conductive paths between two or more electrically conductive contact surfaces. Examples of such structures are described in U.S. Pat. No. 6,365,978 (Ibnabdeljalil et al.) and PCT Publication WO 2006/060495 A1. Problems associated with the foregoing structures, include the permanent nature of solder connections, which prevents easy removal of components from the substrate, and incorrect solder operation, which may result in poor solder joints.

Alternative structures for providing the conductive paths include solderless compression contacts, such as those described in U.S. Pat. No. 7,726,984 (Bumb, Jr. et al), U.S. Pat. No. 6,814,584 (Zaderej), U.S. Pat. No. 6,669,489 (Dozier, I I et al.), U.S. Pat. No. 5,007,841 (Smolley) and U.S. Pat. No. 4,574,331 (Smolley). Problems associated with the foregoing structures, include insufficient contact pressure between the compression contact and the substrate and/or the IC resulting in poor (or in some case, no) electrical connection.

### SUMMARY

Consistent with a first aspect of the present disclosure, an interface for electrically coupling first and second electrically conductive contact surfaces is provided, the interface comprising an insulating substrate having a plurality of openings formed therethrough, and a plurality of conductive connector elements disposed in respective ones of the openings in the insulating substrate, each of the plurality of conductive connector elements including an electrically conductive deformable material and a shape-memory alloy, wherein the shape-memory alloy and the electrically conductive deformable material of each of the plurality of conductive connector elements are mechanically coupled such that a thermally induced deformation of the shape-memory alloy causes a mechanical deformation of the electrically conductive deformable material and thereby aids in the electrical coupling of the first and second electrically conductive contact surfaces through the connector element.

In the interface consistent with the first aspect of the present disclosure, the substrate comprises a non-conducting polymer, a glass reinforced epoxy resin, mica or a ceramic.

In the interface consistent with the first aspect of the present disclosure, the insulating substrate includes first and second opposing outer surfaces, each of the plurality of openings in the insulating substrate extends from the first outer surface to the second outer surface, and each of the plurality of conductive connector elements is disposed in a respective one of the openings in the insulating substrate such that at least a portion of the conductive connector element extends beyond the first outer surface of the insulating substrate.

In the interface consistent with the first aspect of the present disclosure, a structure of the electrically conductive material includes at least one of one of a wound metal wire and a spring element.

In the interface consistent with the first aspect of the present disclosure, each of the connector elements further includes one or more rigid conductive members.

In the interface consistent with the first aspect of the present disclosure, the shape-memory alloy comprises at least one of a copper-aluminum-nickel alloy, a nickel-titanium alloy, a zinc alloy, a copper alloy, a gold alloy and an iron alloy.

In the interface consistent with the first aspect of the present disclosure, the shape-memory alloy is embedded within the electrically conductive deformable material.

In the interface consistent with the first aspect of the present disclosure, the shape-memory alloy is disposed adjacent to the electrically conductive deformable material such that the shape-memory alloy exhibits a mechanical force on the electrically conductive material during the thermally induced deformation of the shape-memory alloy.

Consistent with a second aspect of the present disclosure, an integrated circuit (IC) package structure is provided, comprising an integrated circuit (IC) chip having a plurality of electrically conductive contact surfaces, a circuit board having a plurality of electrically conductive contact surfaces and an interface for electrically coupling the electrically conductive contact surfaces of the IC chip to respective ones of the electrically conductive contact surfaces of the circuit board, wherein the interface includes an insulating substrate having a plurality of openings formed therethrough, and a plurality of conductive connector elements disposed in respective ones of the openings in the insulating substrate, each of the plurality of conductive connector elements including an electrically conductive deformable material and a shape-memory alloy, and wherein the shape-memory alloy and the electrically conductive deformable material of each of the plurality of connector elements are mechanically coupled such that a thermally induced deformation of the shape-memory alloy causes a mechanical deformation of the electrically conductive deformable material and thereby aids in the electrical coupling of the electrically conductive contact surfaces of the IC chip to the respective ones of the electrically conductive contact surfaces of the circuit board through the connector element.

In the IC package structure consistent with the second aspect of the present disclosure, the substrate is one of a rigid substrate and a flexible substrate.

In the IC package structure consistent with the second aspect of the present disclosure, the insulating substrate includes first and second opposing outer surfaces, each of the plurality of openings in the insulating substrate extends from the first outer surface to the second outer surface, and each of the plurality of conductive connector elements is disposed in a respective one of the openings in the insulating substrate such that at least a first portion of the conductive connector element extends beyond the first outer surface of the insulating substrate and at least a second portion of the conductive connector element extends beyond the second outer surface of the insulating substrate.

In the IC package structure consistent with the second aspect of the present disclosure, the shape-memory alloy exhibits a one-way shape memory effect.

In the IC package structure consistent with the second aspect of the present disclosure, the shape-memory alloy exhibits a multi-way shape memory effect.

In the IC package structure consistent with the second aspect of the present disclosure, the shape-memory alloy is shaped to mechanically engage the electrically conductive material during the thermally induced deformation of the shape-memory alloy.

In the IC package structure consistent with the second aspect of the present disclosure, a structure of the shape-memory alloy is one or more of a coil, a spring, a zigzag, and a sphere.

In the IC package structure consistent with the second aspect of the present disclosure, a structure of the shape-memory alloy comprises a plurality of strands of the shape-memory alloy.

In the IC package structure consistent with the second aspect of the present disclosure, the IC is a photonic integrated circuit (PIC), a field programmable gate array (FPGA) a digital signal processor (DSP), a microprocessor, or an application-specific integrated circuit (ASIC).

Consistent with a third aspect of the present disclosure, a conductive connector element for use with a rigid or flexible insulating substrate to electrically couple first and second electrically conductive contact surfaces, the conductive connector element is provided, comprising an electrically conductive deformable material, and a shape-memory alloy, wherein the conductive connector element is sized and shaped to fit in an opening provided through the insulating substrate, and wherein the shape-memory alloy and the electrically conductive deformable material are mechanically coupled such that a thermally induced deformation of the shape-memory alloy causes a mechanical deformation of the electrically conductive deformable material and thereby aids in the electrical coupling of the first and second electrically conductive contact surfaces through the connector element when the connector element is disposed in the opening provided through the insulating substrate.

In the conductive connector element consistent with the third aspect of the present disclosure, a structure of the electrically conductive material comprises at least one of a wound metal wire and a spring element.

In the conductive connector element consistent with the third aspect of the present disclosure, the shape-memory alloy comprises at least one of a copper-aluminum-nickel alloy, a nickel-titanium alloy, a zinc alloy, a copper alloy, a gold alloy and an iron alloy.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1 illustrates a perspective view of an interface consistent with one aspect of the present disclosure;

FIG. 2 illustrates an example of an electrically conductive deformable material structure consistent with one aspect of the present disclosure;

FIG. 3 illustrates an example of a shape-memory alloy structure consistent with one aspect of the present disclosure;

FIG. 4A illustrates the shape-memory alloy structure of FIG. 3 prior to a thermally-induced deformation of the shape-memory alloy structure;

FIG. 4B illustrates the shape-memory alloy structure of FIG. 3 subsequent to a thermally-induced deformation of the shape-memory alloy structure;

FIG. 5A illustrates an example of a conductive connector element prior to a thermally-induced deformation of the shape-memory alloy structure consistent with one aspect of the present disclosure;

FIG. 5B illustrates an example of a conductive connector element subsequent to a thermally-induced deformation of the shape-memory alloy structure consistent with one aspect of the present disclosure;

FIG. 6A illustrates the insertion of the conductive connector element of FIG. 5A in an opening of an insulating substrate consistent with one aspect of the present disclosure;

FIG. 6B illustrates the conductive connector element and insulating substrate of FIG. 6A prior to a thermally-induced deformation of the shape-memory alloy;

FIG. 6C illustrates the conductive connector element and insulating substrate of FIG. 6A subsequent to a thermally-induced deformation of the shape-memory alloy;

FIGS. 7A and 7B illustrate the conductive connector element and insulating substrate of FIGS. 6A-C together with first and second electrically conductive contact surfaces;

FIGS. 8, 9A, 9B, 10A, 10B, 10C and 10D illustrate examples of conductive connector elements and insulating substrates consistent with additional aspects of the present disclosure;

FIGS. 11A, 11B, 12A, 12B, 13A, 13B, 14A, 14B, 15A, 15B, 16A, 16B, 17A, 17B, 18A and 18B illustrate examples of shape-memory alloy structures consistent with additional aspects of the present disclosure;

FIG. 19 illustrates an integrated circuit (IC) package structure consistent with an aspect of the present disclosure; and

FIG. 20 illustrates an exploded perspective view of the IC package structure of FIG. 19.

### DESCRIPTION OF THE EMBODIMENTS

Consistent with a first aspect of the present disclosure, an interface for electrically coupling first and second electrically conductive contact surfaces is provided, the interface comprising an insulating substrate having a plurality of openings formed therethrough, and a plurality of conductive connector elements disposed in respective ones of the openings in the insulating substrate, each of the plurality of conductive connector elements including an electrically conductive deformable material and a shape-memory alloy, wherein the shape-memory alloy and the electrically conductive deformable material of each of the plurality of conductive connector elements are mechanically coupled such that a thermally induced deformation of the shape-memory alloy causes a mechanical deformation of the electrically conductive deformable material and thereby aids in the electrical coupling of the first and second electrically conductive contact surfaces through the connector element.

Consistent with a second aspect of the present disclosure, an integrated circuit (IC) package structure is provided, comprising an integrated circuit (IC) chip having a plurality of electrically conductive contact surfaces, a circuit board having a plurality of electrically conductive contact surfaces and an interface for electrically coupling the electrically conductive contact surfaces of the IC chip to respective ones of the electrically conductive contact surfaces of the circuit board, wherein the interface includes an insulating substrate having a plurality of openings formed therethrough, and a plurality of conductive connector elements disposed in respective ones of the openings in the insulating substrate, each of the plurality of conductive connector elements including an electrically conductive deformable material and a shape-memory alloy, and wherein the shape-memory alloy and the electrically conductive deformable material of each of the plurality of connector elements are mechanically coupled such that a thermally induced deformation of the shape-memory alloy causes a mechanical deformation of the electrically conductive deformable material and thereby aids in the electrical coupling of the electrically conductive contact surfaces of the IC chip to the respective ones of the electrically conductive contact surfaces of the circuit board through the connector element.

Consistent with a third aspect of the present disclosure, a conductive connector element for use with a rigid or flexible insulating substrate to electrically couple first and second electrically conductive contact surfaces, the conductive connector element is provided, comprising an electrically conductive deformable material, and a shape-memory alloy, wherein the conductive connector element is sized and shaped to fit in an opening provided through the insulating substrate, and wherein the shape-memory alloy and the electrically conductive deformable material are mechanically coupled such that a thermally induced deformation of the shape-memory alloy causes a mechanical deformation of the electrically conductive deformable material and thereby aids in the electrical coupling of the first and second electrically conductive contact surfaces through the connector element when the connector element is disposed in the opening provided through the insulating substrate.

Various examples of interfaces, IC package structures and conductive connector elements, each consistent with the present disclosure, are discussed below. Reference will now be made in detail to the present exemplary embodiments of the present disclosure, which are illustrated in the accompanying drawings. Wherever possible, the same reference numbers will be used throughout the drawings to refer to the same or like parts.

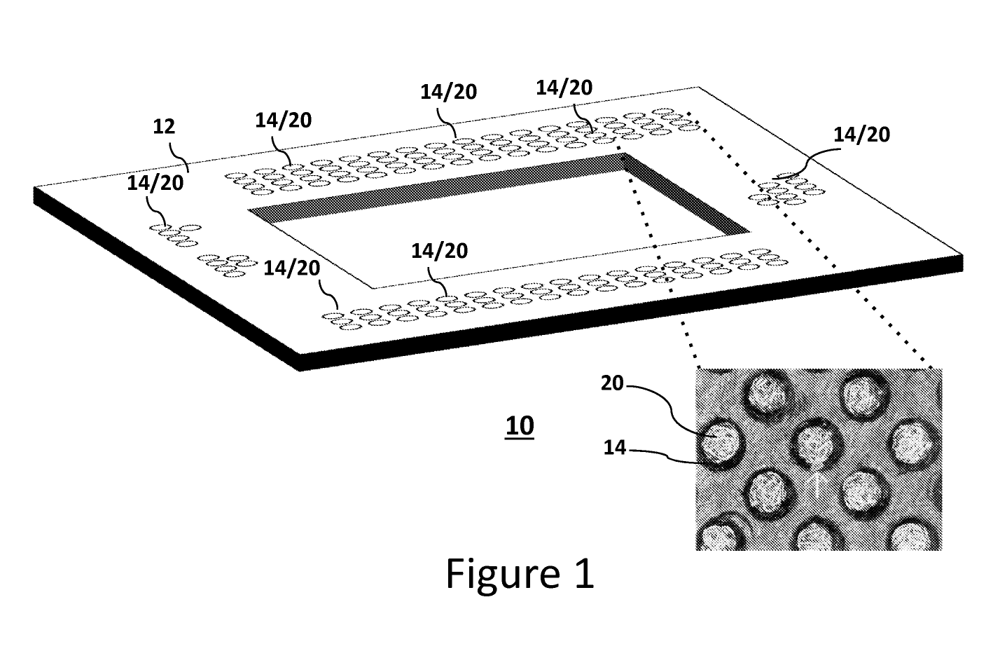

FIG. 1 illustrates a perspective view of an interface 10 consistent with one aspect of the present disclosure. As shown in FIG. 1, interface 10 comprises an insulating substrate 12. Insulating substrate 12 may be a rigid substrate or a flexible substrate and may comprise, for example, a non-conducting polymer, a glass reinforced epoxy resin (e.g., FR-4), mica or a ceramic. Insulating substrate 12 may comprise other materials know to those skilled in the art for providing an insulating substrate suitable for use in the manufacture of electronic devices and assemblies.

As further shown in FIG. 1, insulating substrate 12 includes a plurality of openings 14 formed therethrough. Preferably, openings 14 extend between the outer opposing surfaces of substrate 12 as illustrated in FIG. 1. The number of openings 14 and their arrangement may be selected based on the application with which interface 10 is to be used. In addition, openings 14 may be of any shape or size deemed suitable for the application with which interface 10 is to be used. Preferably, openings 14 are either cylindrically shaped or have an hourglass shape.

Interface 10 further comprises a plurality of conductive connector elements 20 disposed in respective ones of openings 14. Each of conductive connector elements 20 includes an electrically conductive deformable material and a shape-memory alloy.

The electrically conductive deformable material may comprise, for example, silver, copper, gold, or aluminum. Other electrically conductive deformable materials know to those skilled in the art to be suitable for use in the manufacture of electronic devices or assemblies may also be used. Preferably, the electrically conductive deformable material has as a structure that is sized and shaped for insertion, together with the shape-memory alloy, into openings 14 of substrate 12 and that allows the electrically conductive deformable material to mechanically deform upon a thermally induced deformation of the shape-memory alloy when the electrically conductive deformable material and the shape-memory alloy are mechanically coupled as described in more detail below. For example, the electrically conductive deformable material may be provided in the form of a CIN::APSE® contact, which is sold by Cinch Connectors (www.cinch.com). Another suitable structure is the Fuzz Button®, which is sold by Custom Interconnections, LLC (www.custominterconnects.com). CIN::APSE® contacts and Fuzz Buttons® comprise cylinders of finely compressed metal wire that is wound to form an individual unit of certain diameter and length. Additional information regarding the CIN::APSE® compression interconnect technology is described in US Publication US20100055990 A1 and additional information regarding Fuzz Buttons® is described in European Publication EP0127377 B1, both of which are incorporated by reference herein. Alternative structures of the electrically conductive deformable material include one or more spring elements, such as a leaf spring. As will be explained in more detail below, any of the foregoing structures may be used alone or in combination with one or more rigid conductive members to form the conductive connector elements.

As used herein, the term “shape-memory alloy” means a metal alloy that, when deformed, returns to its pre-deformed shape when heated. When a shape-memory alloy is in its cold state, the metal can be deformed and will hold the deformed shape until heated above its transition temperature. Upon heating above its transition temperature, the material changes to its original, pre-deformed shape. When the material cools again it will remain in the pre-deformed shape, until deformed again. Examples of shape-memory alloys include copper-aluminum-nickel alloy, a nickel-titanium alloy, a zinc alloy, a copper alloy, a gold alloy and an iron alloy. The shape-memory alloy may exhibit a one-way shape memory effect or a multi-way shape memory effect. Other shape-memory alloys know to those skilled in the art may also be used. Preferably, the shape-memory alloy has as a structure that is sized and shaped for insertion, together with the electrically conductive deformable material, into openings 14 of substrate 12 and that causes a mechanical deformation of the electrically conductive deformable material upon a thermally induced deformation of the shape-memory alloy when the electrically conductive deformable material and the shape-memory alloy are mechanically coupled as described in more detail below. For example, the shape-memory alloy may be provided in the form of a coil, spring, zigzag, or sphere, or a combination of one or more of the foregoing.

Consistent with one aspect of the present disclosure, the shape-memory alloy and electrically conductive deformable material of each of connector elements 20 are mechanically coupled such that a thermally induced deformation of the shape-memory alloy causes a mechanical deformation of the electrically conductive deformable material. For example, the shape-memory alloy may be embedded within the electrically conductive deformable material. Alternatively, the shape-memory alloy may be disposed adjacent to the electrically conductive deformable material such that the shape-memory alloy exhibits a mechanical force on the electrically conductive deformable material, and thus causes a mechanical deformation of the electrically conductive deformable material, during the thermally induced deformation of the shape-memory alloy. For example, the shape-memory alloy may be attached to, or otherwise in physical contact with, two points, preferably at the endpoints or near the endpoints, of the electrically conductive deformable material. Heating of the shape-memory alloy may be achieved in any number of ways, including by the internal heat build up from operation of the device with which the interface 10 is to be used, the application of heat when the device is placed in a heated environmental chamber to test its performance, or the application of heat by an external source, such as a heat gun.

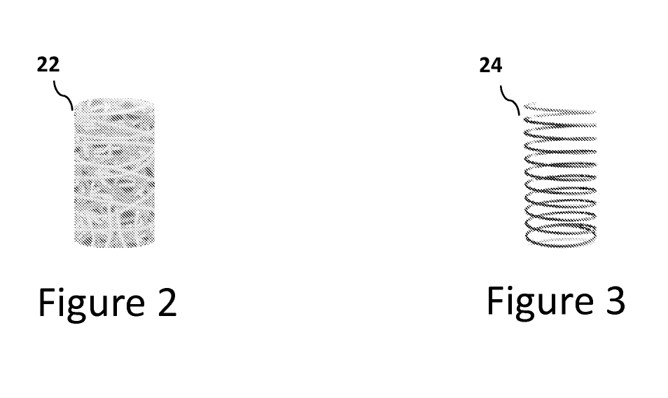

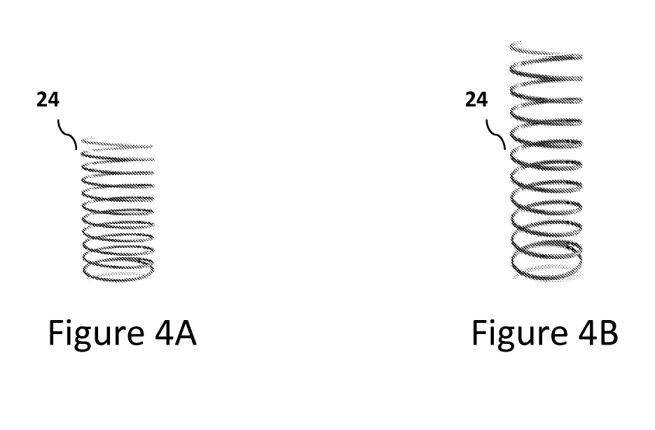

FIG. 2 and FIG. 3 illustrate example structures of the electrically conductive deformable material and shape-memory alloy, respectively, which are suitable for use as the connector element 20. Structure 22 of the electrically conductive deformable material (FIG. 2) comprises a cylinder of finely compressed metal wire that is wound to form an individual unit of certain diameter and length and is similar to the CIN::APSE® contact and Fuzz Buttons® described above. Structure 24 of the shape-memory alloy (FIG. 3) is a coil. FIG. 4A illustrates the shape-memory alloy structure 24 of FIG. 3 in its deformed state. As shown in FIG. 4A, when in its deformed state, the shape-memory alloy structure 24 has the form of a compressed coil. FIG. 4B illustrates the shape-memory alloy structure 24 of FIG. 3 in its pre-deformed state, after it has been heated above its transition temperature. As shown in FIG. 4B, when in its pre-deformed state, the shape-memory alloy structure 24 has the form of an extended coil.

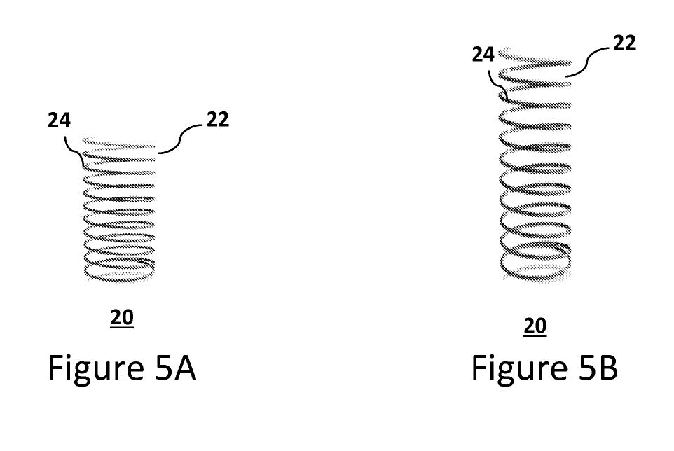

As shown in FIG. 5A, shape-memory alloy structure 24 in its deformed state (FIG. 4A) may be imbedded in electrically conductive deformable material structure 22 to provide connector element 20. Upon heating of connector element 20 above the transition temperature of shape-memory alloy structure 24, shape-memory alloy structure 24 returns to its pre-deformed state (FIG. 4B). This thermally induced deformation of shape-memory alloy structure 24 causes a mechanical deformation of electrically conductive deformable material structure 22, which results in an extension of connector element 20 as shown in FIG. 5B.

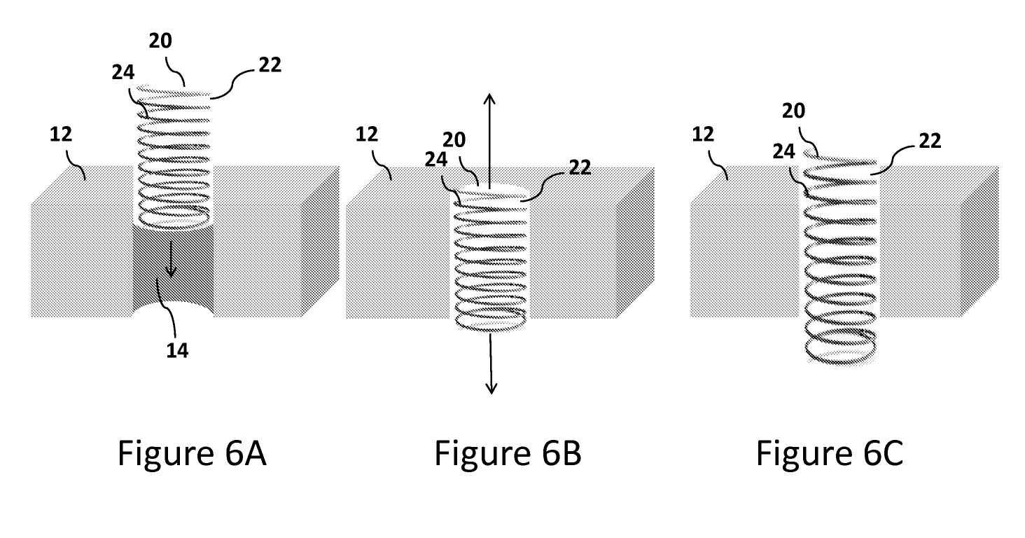

FIG. 6A illustrates the placement of connector element 20 into an opening 14 of substrate 12. As shown in FIG. 6B, connector element 20 is positioned within opening 14 such that both ends of connector element 20 extend beyond the outer surfaces of substrate 12. Alternatively, connector element 20 may be positioned within opening 14 such that only one end of connector element 20 extends beyond the respective outer surface of substrate 12, or such that neither end of connector element 20 extends beyond the respective outer surface of substrate 12.

As shown in FIG. 6C, upon heating of connector element 20 above the transition temperature of shape-memory alloy structure 24, shape-memory alloy structure 24 returns to its pre-deformed state. This thermally induced deformation of shape-memory alloy structure 24 causes a mechanical deformation of electrically conductive material structure 22, which results in an extension of connector element 20 as shown in FIG. 6C.

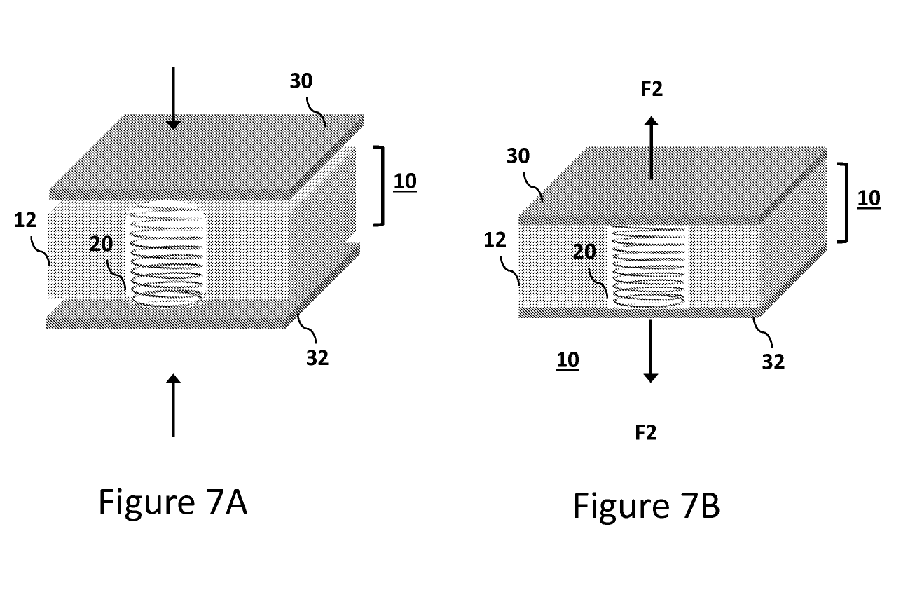

FIGS. 7A and 7B illustrate a portion of interface 10 electrically coupling first electrically conductive contact surface 30 and second electrically conductive contact surface 32. Contact surfaces 30 and 32 may be, for example, conductive contact surfaces of a pin grid array (“PGA”), ball grid array (“BGA”), land grid array (“LGA”), and/or column grid array (“CGA”) packaging structure, a circuit board, and/or an IC chip package. As shown in FIG. 7A, contact surfaces 30 and 32 are secured to interface 10 by adhesive, bolts or other technique known to those skilled in the art. To the extent that one or both ends of connector element 20 extend beyond the outer surface(s) of substrate 12, contact surfaces 30 and 32 will compress the ends of connector element 20 against contact surfaces 30 and 32. It should be appreciated that such compression aids in the electrical coupling of contact surfaces 30 and 32 through connector element 20. As shown in FIG. 7B, upon heating of connector element 20 above the transition temperature of shape-memory alloy structure 24, connector element 20 extends, as described above, to exert an additional force F2 against contact surfaces 30 and 32, which thereby further aids in the electrical coupling of contact surfaces 30 and 32 through connector element 20. It should be appreciated that compression of the ends of connector element 20 against contact surfaces 30 and 32 may also result from only the thermally induced deformation of shape-memory alloy structure 24, in particular, in the case where the ends of connector element 20 (when shape-memory alloy structure 24 is in the deformed state) do not extend beyond the respective outer surfaces of substrate 12.

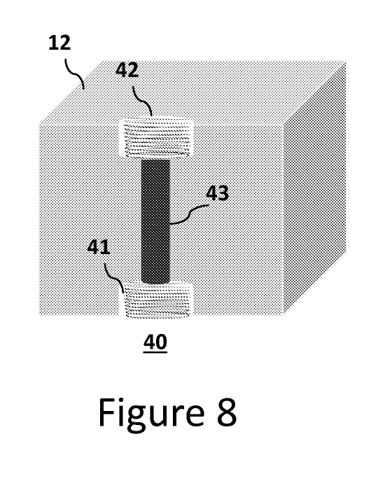

FIGS. 8, 9A, 9B, 10A, 10B, 10C and 10D illustrate examples of alternative structures that may be used in lieu of connector element 20 of FIG. 5A consistent with aspects of the present disclosure.

Connector element 40 of FIG. 8 includes two structures 41 an 42, each of which is similar to connector element 20 of FIG. 5A, separated by a rigid conductive member 43. Rigid conductive member 43 comprises, for example, a gold-plated brass cylinder and provides connector element 40 with increased height over connector element 20. The configuration of FIG. 8 is particular useful when multiple points of contact are needed in a tall connector.

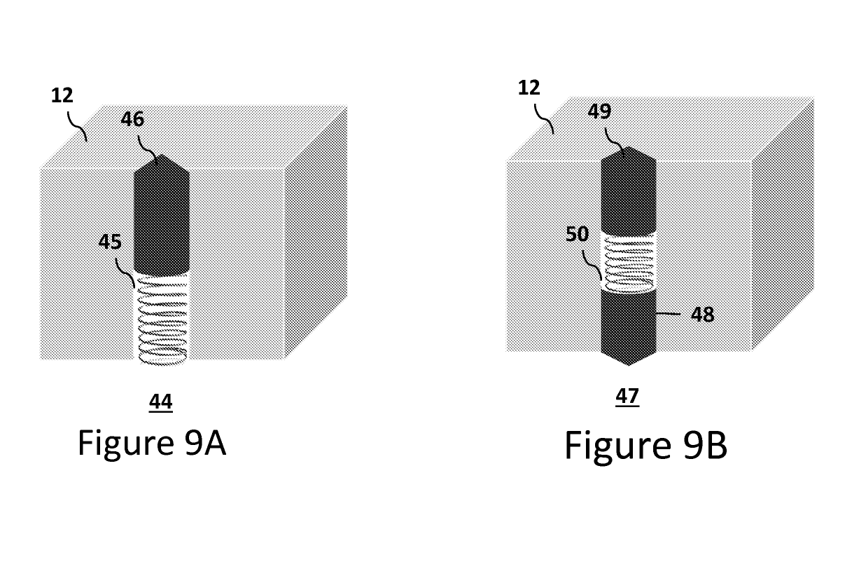

Connector element 44 of FIG. 9A includes structure 45, which is similar to connector element 20 of FIG. 5A, and rigid conductive member 46. Rigid conductive member 46 comprises, for example, a gold-plated brass cylinder with a pointed tip. The configuration of FIG. 9A is particularly useful for board-to-board or test applications.

Connector element 47 of FIG. 9B includes two rigid conductive members 48 and 49, each of which is similar to rigid conductive member 46 of FIG. 9A, separated by structure 50, which is similar to connector element 20 of FIG. 5A. This configuration is particularly useful for parallel board-to-board stacking connector applications.

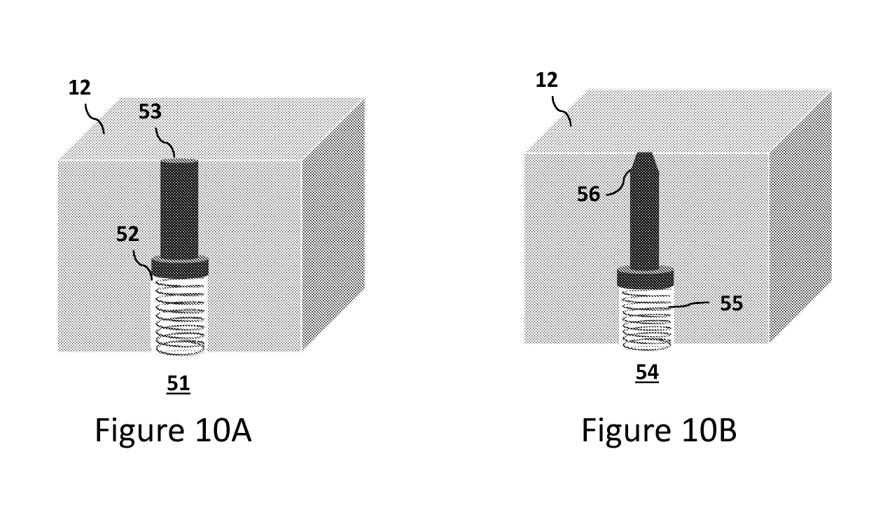

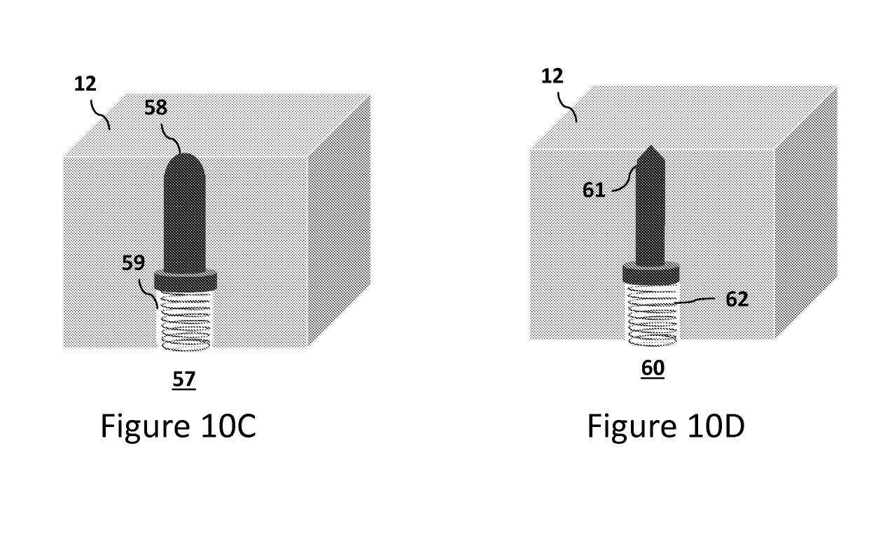

Connector element 51 of FIG. 10A includes structure 52, which is similar to connector element 20 of FIG. 5A, and rigid conductive member 53. Similarly, connector element 54 of FIG. 10B includes structure 55, which is similar to connector element 20 of FIG. 5A, and rigid conductive member 56, connector element 57 of FIG. 10C includes structure 59, which is similar to connector element 20 of FIG. 5A, and rigid conductive member 58, and connector element 60 of FIG. 10D includes structure 62, which is similar to connector element 20 of FIG. 5A, and rigid conductive member 61. Rigid conductive members 53, 56,58 and 61 comprise, for example, gold-plated Beryllium Copper, and are particularly useful for high mating cycle applications, such as probe tips, test sockets, contractors, test fixtures, and high mating cycle repeatable interconnects. The configuration of FIG. 10A is particularly useful in LGA, QFN and CGA applications, the configuration of FIG. 10B is particularly useful in BGA applications, and the configurations of FIGS. 10C and 10D are particularly useful in LGA applications.

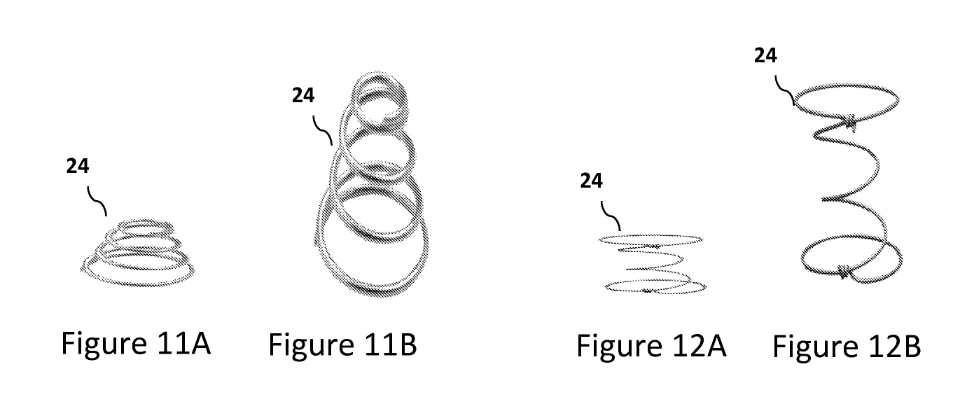

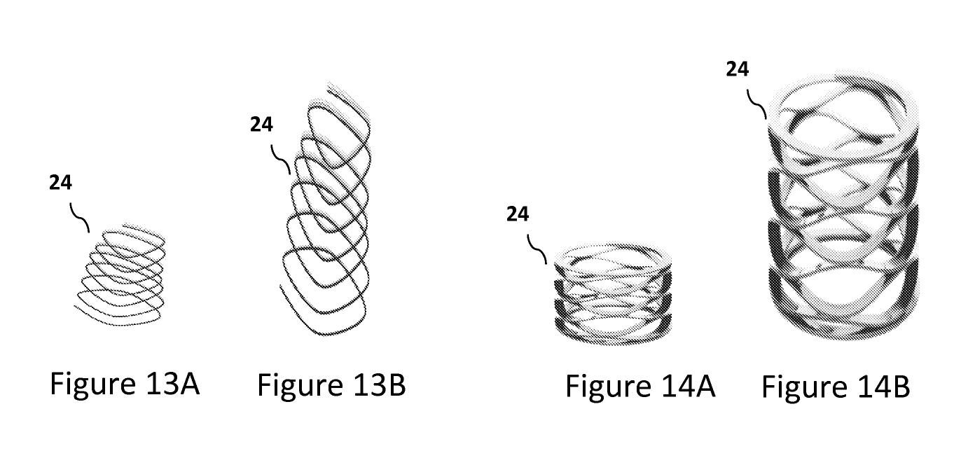

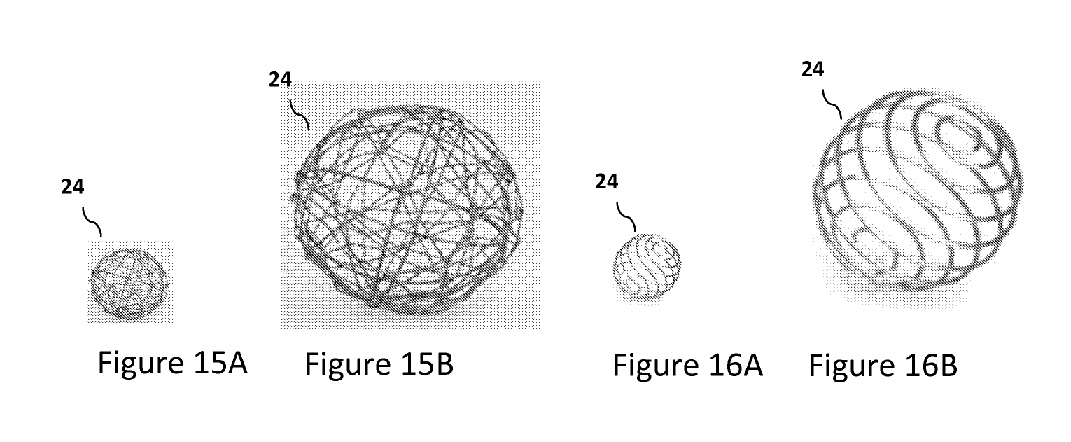

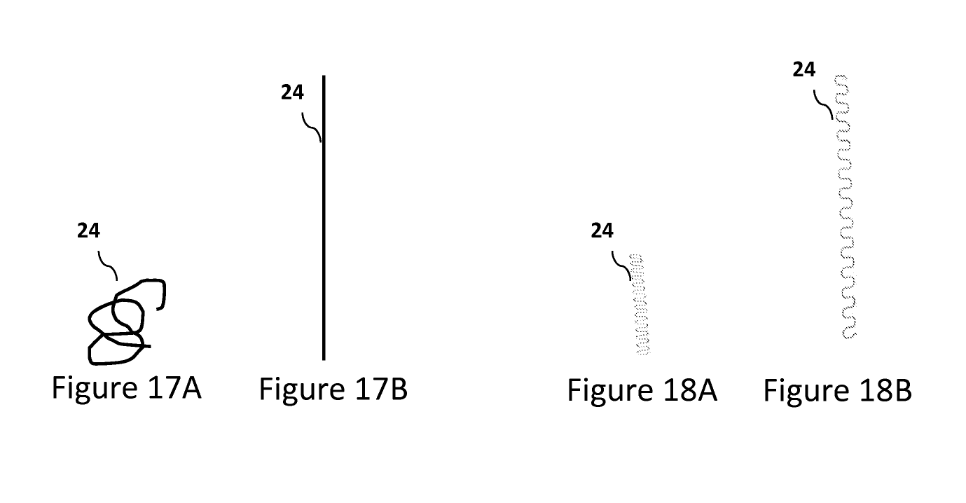

FIGS. 11A, 11B, 12A, 12B, 13A, 13B, 14A, 14B, 15A, 15B, 16A, 16B, 17A, 17B, 18A and 18B illustrate alternative examples of shape-memory alloy structures 24 consistent with additional aspects of the present disclosure. FIGS. 11A, 12A, 13A 14A, 15A, 16A, 17A and 18A illustrate the structures in a deformed state, while FIGS. 11B, 12B, 13B, 14B, 15B, 16B, 17B and 18B illustrate the structures in a pre-deformed state after the structures have been heated above their transition temperatures. In the case of the structures shown in FIGS. 15A, 15B, 16A, 16B, 17A, 17B, 18A and 18B, a plurality of such structures may be embedded and randomly dispersed in the electrically conductive deformable material according to the present disclosure.

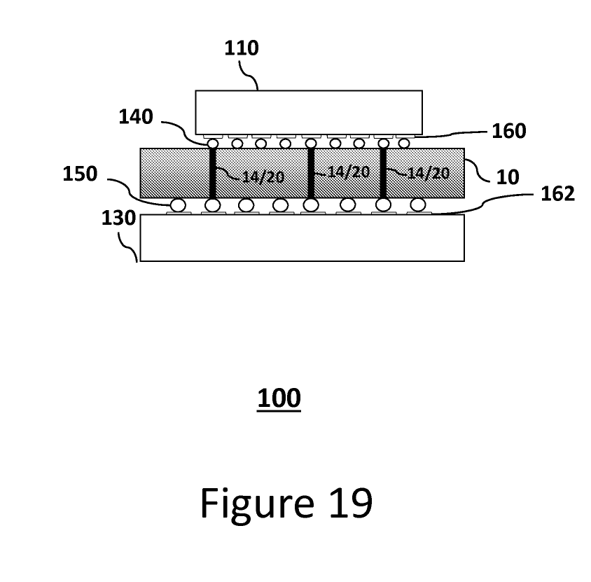

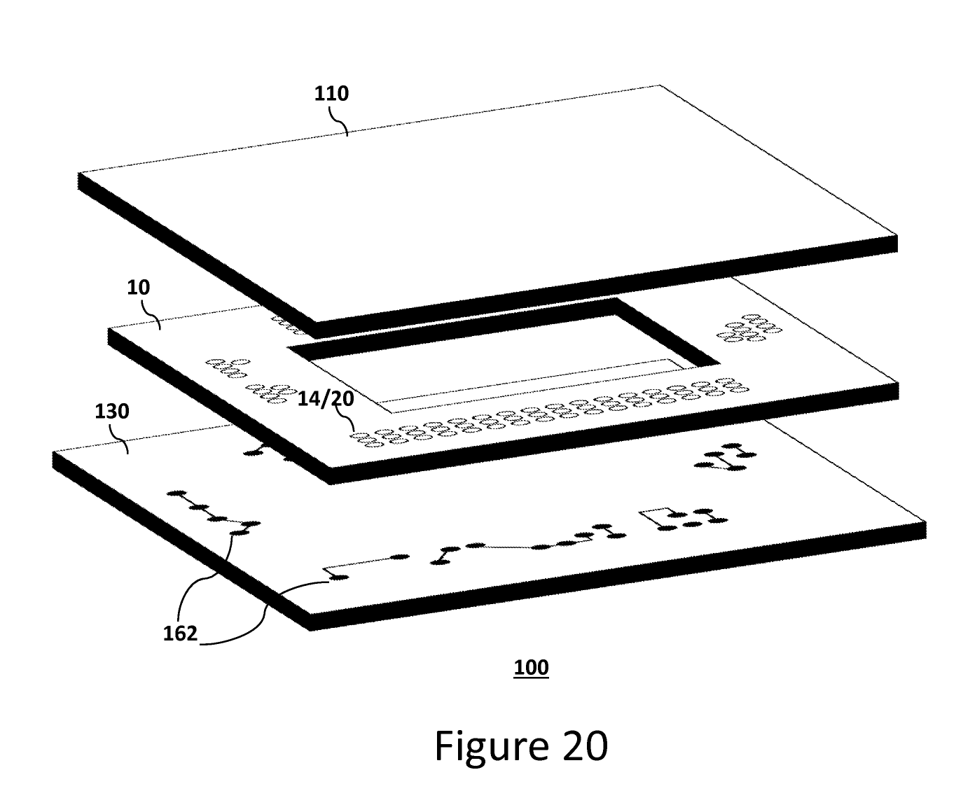

FIG. 19 shows a simplified cross section and FIG. 20 shows a simplified exploded view of an IC package structure 100 (in this case a BGA package structure) according to an aspect of the present disclosure. As shown in FIG. 19, IC package structure 100 includes an IC chip 110 having a plurality of conductive contact pads 160, interface 10 having openings 14 and connector elements 20 as described above, and a circuit board 130 having a plurality of conductive contact pads 162. Contact pads 160 of IC chip are electrically coupled to connector elements 20 of interface 10 through solder balls 140. Similarly, the conductive contact pads 162 of circuit board 130 are electrically coupled to connector elements 20 through solder balls 150. IC chip 110 may comprise any type of IC chip, including a photonic integrated circuit (PIC), a field programmable gate array (FPGA) a digital signal processor (DSP), a microprocessor, or an application-specific integrated circuit (ASIC). As described above, when the shape-memory alloy provided in connector elements 20 is heated above its transition temperature, the shape-memory alloy transitions from its deformed state to its pre-deformed state (i.e., it undergoes thermally induced deformation) causing a mechanical deformation of the electrically conductive deformable material in connector elements 20 and thereby aids in the electrical coupling of contact pads 160 and 162 through connector elements 20.

Other embodiments will be apparent to those skilled in the art from consideration of the specification. It is intended that the specification and examples be considered as exemplary only, with a true scope and spirit of the invention being indicated by the following claims.

What is claimed is:

1. An interface for electrically coupling first and second electrically conductive contact surfaces, the interface comprising:
an insulating substrate having a plurality of openings formed therethrough; and
a plurality of conductive connector elements disposed in respective ones of the openings in the insulating substrate, each of the plurality of conductive connector elements including an electrically conductive deformable material and a shape-memory alloy,
wherein the shape-memory alloy and the electrically conductive deformable material of each of the plurality of conductive connector elements are mechanically coupled such that a thermally induced deformation of the shape-memory alloy causes a mechanical deformation of the electrically conductive deformable material and thereby aids in the electrical coupling of the first and second electrically conductive contact surfaces through the connector element.

2. The interface of claim 1, wherein the substrate comprises a non-conducting polymer, a glass reinforced epoxy resin, mica or a ceramic.

3. The interface of claim 1, wherein:
the insulating substrate includes first and second opposing outer surfaces;
each of the plurality of openings in the insulating substrate extends from the first outer surface to the second outer surface; and
each of the plurality of conductive connector elements is disposed in a respective one of the openings in the insulating substrate such that at least a portion of the conductive connector element extends beyond the first outer surface of the insulating substrate.

4. The interface of claim 1, wherein a structure of the electrically conductive material includes at least one of one of a wound metal wire and a spring element.

5. The interface of claim 1, wherein each of the connector elements further includes one or more rigid conductive members.

6. The interface of claim 1, wherein the shape-memory alloy comprises at least one of a copper-aluminum-nickel alloy, a nickel-titanium alloy, a zinc alloy, a copper alloy, a gold alloy and an iron alloy.

7. The interface of claim 1, wherein the shape-memory alloy is embedded within the electrically conductive deformable material.

8. The interface of claim 1, wherein the shape-memory alloy is disposed adjacent to the electrically conductive deformable material such that the shape-memory alloy exhibits a mechanical force on the electrically conductive material during the thermally induced deformation of the shape-memory alloy.

9. An integrated circuit (IC) package structure, comprising:
an IC chip having a plurality of electrically conductive contact surfaces;
a circuit board having a plurality of electrically conductive contact surfaces; and
an interface for electrically coupling the electrically conductive contact surfaces of the IC chip to respective ones of the electrically conductive contact surfaces of the circuit board,
wherein the interface includes an insulating substrate having a plurality of openings formed therethrough, and a plurality of conductive connector elements disposed in respective ones of the openings in the insulating substrate, each of the plurality of conductive connector elements including an electrically conductive deformable material and a shape-memory alloy, and
wherein the shape-memory alloy and the electrically conductive deformable material of each of the plurality of connector elements are mechanically coupled such that a thermally induced deformation of the shape-memory alloy causes a mechanical deformation of the electrically conductive deformable material and thereby aids in the electrical coupling of the electrically conductive contact surfaces of the IC chip to the respective ones of the electrically conductive contact surfaces of the circuit board through the connector element.

10. The IC package structure of claim 9, wherein the substrate is one of a rigid substrate and a flexible substrate.

11. The IC package structure of claim 9, wherein:
the insulating substrate includes first and second opposing outer surfaces;
each of the plurality of openings in the insulating substrate extends from the first outer surface to the second outer surface; and
each of the plurality of conductive connector elements is disposed in a respective one of the openings in the insulating substrate such that at least a first portion of the conductive connector element extends beyond the first outer surface of the insulating substrate and at least a second portion of the conductive connector element extends beyond the second outer surface of the insulating substrate.

12. The IC package structure of claim 9, wherein the shape-memory alloy exhibits a one-way shape memory effect.

13. The IC package structure of claim 9, wherein the shape-memory alloy exhibits a multi-way shape memory effect.

14. The IC package structure of claim 9, wherein the shape-memory alloy is shaped to mechanically engage the electrically conductive material during the thermally induced deformation of the shape-memory alloy.

15. The IC package structure of claim 9, wherein a structure of the shape-memory alloy is one or more of a coil, a spring, a zigzag, and a sphere.

16. The IC package structure of claim 9, wherein a structure of the shape-memory alloy comprises a plurality of strands of the shape-memory alloy.

17. The IC package structure of claim 9, wherein the IC is a photonic integrated circuit (PIC), a field programmable gate array (FPGA) a digital signal processor (DSP), a microprocessor, or an application-specific integrated circuit (ASIC).

18. A conductive connector element for use with a rigid or flexible insulating substrate to electrically couple first and second electrically conductive contact surfaces, the conductive connector element comprising:
an electrically conductive deformable material; and
a shape-memory alloy,
wherein the conductive connector element is sized and shaped to fit in an opening provided through the insulating substrate, and
wherein the shape-memory alloy and the electrically conductive deformable material are mechanically coupled such that a thermally induced deformation of the shape-memory alloy causes a mechanical deformation of the electrically conductive deformable material and thereby aids in the electrical coupling of the first and second electrically conductive contact surfaces through the connector element when the connector element is disposed in the opening provided through the insulating substrate.

19. The interface of claim 18, wherein a structure of the electrically conductive material comprises at least one of a wound metal wire and a spring element.

20. The interface of claim 18, wherein the shape-memory alloy comprises at least one of a copper-aluminum-nickel alloy, a nickel-titanium alloy, a zinc alloy, a copper alloy, a gold alloy and an iron alloy.
